(19) United States
(12) Patent Application Publication
(10) Pub. No.: US 2012/0293053 A1
(43) Pub. Date: Nov. 22, 2012

(54) CASE FOR DISPLAY DEVICE

(76) Inventors: Ying-Hung LIN, Taipei (TW); Chen-Yuan Lu, Taipei (TW)

(21) Appl. No.: 13/109,501

(22) Filed: May 17, 2011

(51) Int. Cl. H05K 5/02

(52) U.S. Cl. 312/111

(57) ABSTRACT

A case for a display device comprises a front half casing and a rear half casing. The front half casing includes a rim portion and a hollow portion. Preferably, at least one first and second connecting elements are respectively provided at the front and rear half casings and are arranged to be screwable with each other. Preferably, a support element is connected between the front and the rear half casings for maintaining the rear half casing apart from the front half casing at a fixed angle after the case is open. Preferably, a receiving casing for locating an airflow-generated device used for heat dissipation is provided to be in detachable connection with a bottom of the rear half casing for providing airflow into the case. Preferably, a waterproof frame is provided and fastened onto an external surface of the rim portion for waterproof protection.

### BACKGROUND OF THE INVENTION

1. Field of the Invention

The present invention relates to a case for a display device and, more particularly, to a case for a display device with structural improvements capable of facilitating the replacement or cleaning of the components disposed within the display device, of improving the heat dissipation efficiency, and of providing better waterproof protection.

2. Description of the Prior Art

With the dramatic development of the techniques regarding Internet and the wireless communication technology, information becomes easily accessible to everyone and thereby the personal information-related electronic products, such as notebooks, mobile phones, digital cameras, and personal digital assistants, are rapidly developed and grown. Going with this tendency, the demand of display devices is also significantly increased.

A display device usually comprises a case, a display module (such as a liquid crystal display or a touch panel), a backlight module, a light source, and a heat dissipation element. A conventional case for a display device is composed of a housing having an opening and a cover. The heat dissipation element is usually provided on the bottom inside the housing; the backlight module and the light source are arranged inside the housing; and the display module is placed on the backlight module. The cover is fixed to the housing in order to cover the opening.

In view of above structure of the conventional case for a display device, several disadvantages should be mentioned.

As mentioned above, because the demand for digital information is even much more enormous nowadays, display devices are becoming daily necessities for most people. It can be seen that display devices are heavily and frequently used. Under this condition, a breakdown may easily occur in any one of the components in a display device. Meanwhile, after being used for a period of time, a display device may gather lots of dust inside its case. Accordingly, it is necessary to clean the display device regularly so as to maintain its normal performance.

However, since the housing and its cover are fixed with each other, it is quite inconvenient for consumers or even maintenance personnel to open the cover in order to replace any component (such as the display module, the backlight module, the light source, or the heat dissipation element) or clean these components or the interior of the case. Therefore, this inconvenience is the first disadvantage.

Besides, another disadvantage is regarding heat dissipation. Heat dissipation is one among most frequently encountered problems occur in electronic products. As for the electronic products, considerable heat is always produced in accompany with their operation. Excessive heat will not only hinder the normal performance of these electronic products, but also may bring to the components of these electronic products damages varying in degrees. Therefore, how to make heat decapitation most efficiency is always the focus of attention.

A conventional display device is usually equipped with a heat dissipation device as well, such as various kinds of heat fans. However, due to the structural limitation inherent in a conventional case for the display device, the display module and the backlight are usually superimposed with each other. Accordingly, the heat dissipation device is usually arranged between the internal bottom surface of the case and the backlight module in order to establish an airflow communication between the outside and inside of the case. This arrangement inevitably makes it less efficient for the heat dissipation device to dissipate the produced heat.

In order to improve the above-mentioned structural disadvantages occur in a conventional display device, the inventor had the motive to try and develop the present invention after hard research to provide a case for a display device possessing structural improvements for achieving desired effects of facilitating the replacement or cleaning of the components disposed within the display device, improving the heat dissipation efficiency, and providing better waterproof protection.

### SUMMARY OF THE INVENTION

One object of the present invention is to provide a case for display device for facilitating the replacement or cleaning of the components disposed within the display device by means of providing two corresponding sets of connecting element(s) that are screwable with each other and respectively at the peripheries of two half casings of the case.

Another object of the present invention is to provide a case for display device comprising at least a support element that is provided between the two half casings for maintaining one half casing apart from another half casing at a fixed angle after the case is open so as to facilitate the replacement or cleaning of the components disposed within the display device.

Another object of the present invention is to provide a display device case comprising a receiving casing for locating an airflow generated device therein used for heat dissipation, where the receiving casing detachably connected to the bottom of the case so that the airflow generated by above device can flow into the case.

Another object of the present invention is to provide a display device case having a waterproof frame for providing the case better waterproof protection.

In order to achieve above object, the present invention provides a case for display device comprising a front half casing, a rear half casing, at least one first connecting element, and at least one second connecting element. The front half casing includes a rim portion and a hollow portion, and the rim portion is adapted for holding edges of a display module so as to locate the display module in the hollow portion. The rear half casing is adapted to receive a light source and a backlight module and one side thereof is pivotally connected with one side of the front half casing. Said at least one first connecting element is provided at the peripheries of the front half casing while said at least one second connecting element is provided at the peripheries of the front half casing corresponding to the location of the first connecting element. Each second connecting element is screwable with one of the at least one first connecting element.

In implementation, each first connecting element is a captive screw fastener and each second connecting element is a seat having a threaded hole, or each first connecting element is a seat having a threaded hole and each second connecting element is a captive screw fastener.

In implementation, the case for display device preferably further comprises at least a support element, connected between the front and the rear half casings. Preferably, each support element can be a pneumatically actuated support element or a compressible elastic member. Alternatively, each support element has one end secrewable with one of the front and rear half casings while has another end pivotally connectable with the other of the front and rear half casings.

In implementation, the case for display device preferably further comprises a receiving casing for locating an airflow generated device therein used for heat dissipation, where the receiving casing is detachably connected to a bottom of the rear half casing and has a first aperture that is arranged correspondingly to a second aperture arranged on the rear half casing; thereby the airflow generated by the air-flow generated device is able to flow into the case via the first and the second apertures.

In implementation, the case for display device preferably further comprises a waterproof frame that is fastened onto an external surface of the rim portion adjacent to the peripheries of the hollow portion, wherein the waterproof frame has an external surface on four sides of which is respectively provided with a downward-sloping part.

The following detailed description, given by way of examples and not intended to limit the invention solely to the embodiments described herein, will best be understood in conjunction with the accompanying drawings.

### BRIEF DESCRIPTION OF THE DRAWINGS

FIG. 1 is a perspective view of a case for a display device according to the present invention, where a receiving casing is separated from a rear half casing.

FIG. 2 is a perspective view of the case for a display device according to the present invention, where the receiving casing is connected to the rear half casing.

FIG. 3 shows a partial cross-sectional view of the case in FIG. 2.

FIG. 4 is a schematic view of the case for a display device according to the present invention, where a first embodiment of the support element is provided and connected between the front and rear half casings.

FIG. 4A is a schematic view of the case for a display device according to the present invention, where a second embodiment of the support element is provided and connected between the front and rear half casings.

FIG. 5 is a schematic view of the case for a display device according to the present invention, where one end of the support element is detached from the rear having casing.

FIG. 5A is a perspective view of the case for a display device according to the present invention, where the second embodiment of the support element is used.

FIG. 6 is a side view of the case for a display device according to the present invention, where the receiving casing is connected to the rear half casing.

FIG. 7 is a schematic view showing the front side of the front half casing of the case according to the present invention.

FIG. 8 is a schematic view showing the front of a waterproof frame according to the present invention.

FIG. 9 is a schematic view showing the backside of the waterproof frame according to the present invention.

### DETAILED DESCRIPTION OF THE PREFERRED EMBODIMENTS

The present invention discloses a case for a display device. The case comprises a front half casing and a rear half casing. The front half casing includes a rim portion and a hollow portion. The rear half casing is connectable with the front half casing.

The present invention mainly comprises four structural improvements as follows: first, a structural improvement for facilitating the opening and the closing of the case; second, a structural improvement for providing a support between the front half casing and the rear half casing in order to locate the casings at fixed relative positions to each other; third, a structural improvement for better heat dissipation efficiency; and fourth, a structural improvement for waterproof protection. In implementation, according to the present invention, any one of the four improvements or combinations of any least two of them can be adopted. These four structural improvements will be illustrated in details by following descriptions together with accompanying figures.

Structural improvement for facilitating the opening and closing of the case:

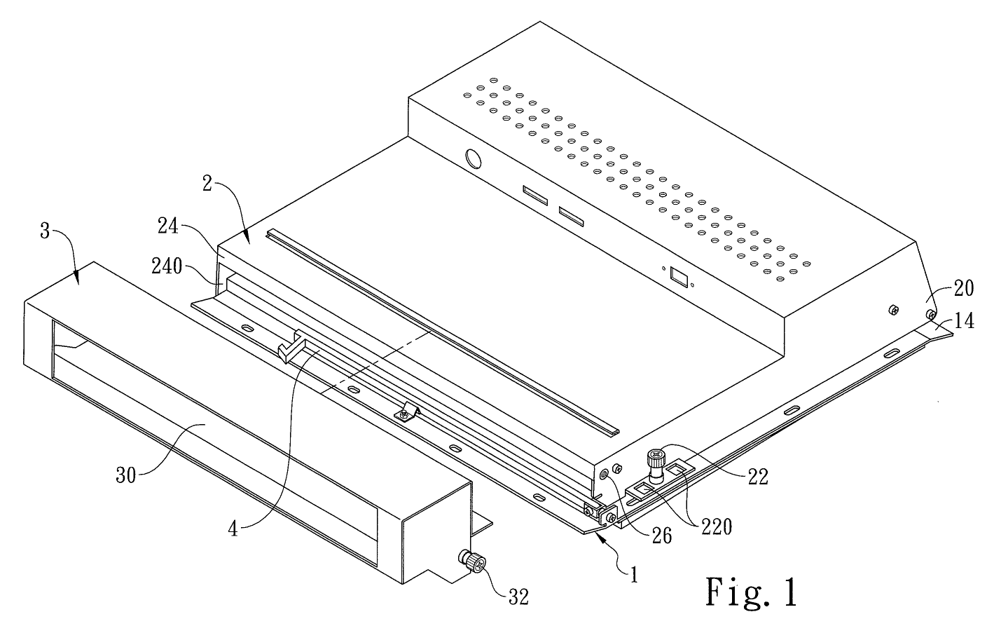

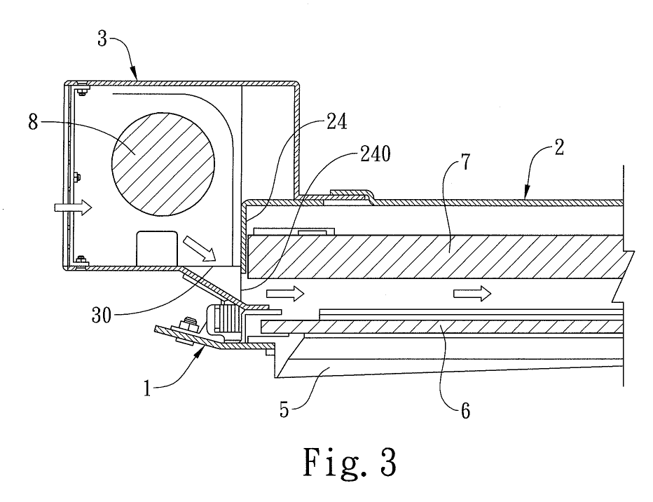

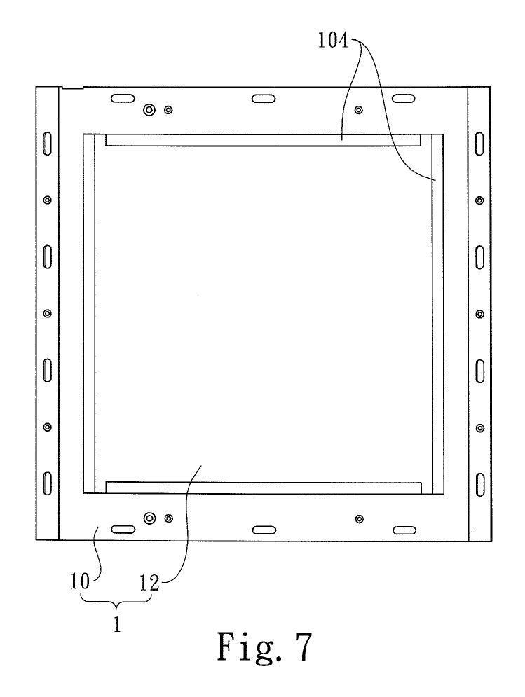

Please refer to FIGS. 1, 3, 5, 6 and 7, where one embodiment of the case for a display device is illustrated. In this embodiment, the case comprises a front half casing 1, a rear half casing 2, two first connecting elements 102, and two second connecting elements. As shown in FIG. 7, the front half casing 1 includes a rim portion 10 and a hollow portion 12. The rim portion 10 is adapted for holding a display module. For example, as shown in FIGS. 3 and 7, four L-shaped holders 104 are provided on the internal peripheries of the internal portion 10 so as to hold a display module 6 beneath the hollow portion 12. The rear half casing 2 is adapted to receive a light source (not shown in figures) and a backlight module 7 and one side 20 thereof is pivotally connected with one side 14 of the front half casing 1.

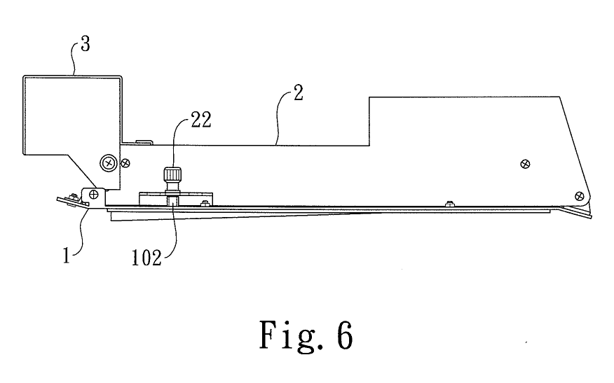

In this embodiment, each of above two first connecting elements 102 is a seat having a threaded hole and is disposed at one lateral side of the front half casing 1. As shown in FIG. 6, each of the two second connecting elements is a captive screw fastener 22 that is disposed at a protrusion that is located at one lateral side of the rear half casing 2. Besides, referring to FIG. 1, the protrusion also includes two holes 220 arranged adjacent to the captive screw fastener 22. The first connecting element 102 is thereby screwable with the captive screw fastener 22 (i.e. the second connecting element). It should be noted that, however, above embodiment is only used for illustration. In implementation, the first connecting element also can be a captive screw fastener while the second connecting element is a seat having a threaded hole.

Accordingly, the case can be open by unscrewing the captive screw fasteners 22 (the two second connecting elements) from the threaded seats (the first connecting element 102). In this way, it is more convenient for users to handle the replacement of any component inside the case or the cleaning of the interior of the case. After that, the case can be closed easily by re-screwing the captive screw fasteners with the threaded seats.

Structural improvement for maintaining the two half casings apart at a fixed angle from each other after the case is open:

This structural improvement includes two embodiments providing different kinds of support elements, each of which is provided and connected between the front half casing and the rear half casing of the case.

Referring to FIGS. 1, 4 and 5, a first embodiment of the support element according to the present invention is illustrated. As shown in these figures, one end 42 of the support element 4 is pivotally connected to the front half casing 1, whereas another end 40 is a free end and is provided with a first connecting part (a seat having threaded hole) 402 and two protruding parts 404 arranged adjacent to the first connecting part 402.

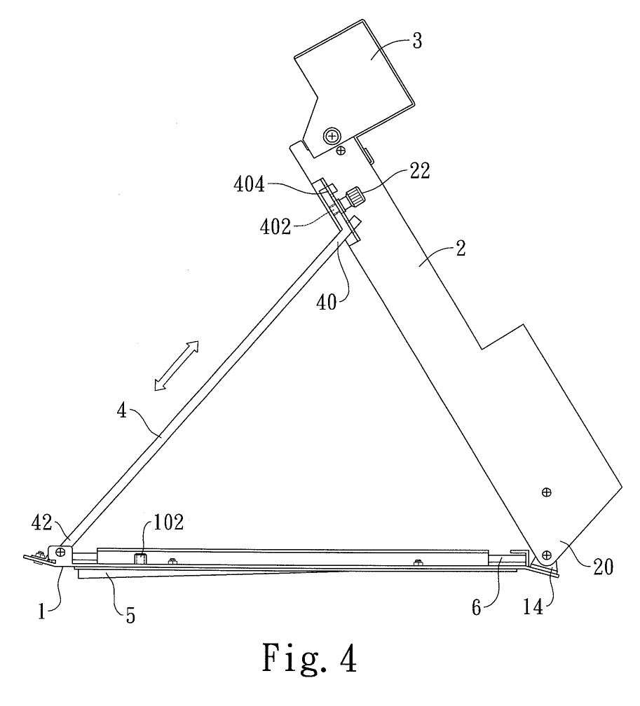

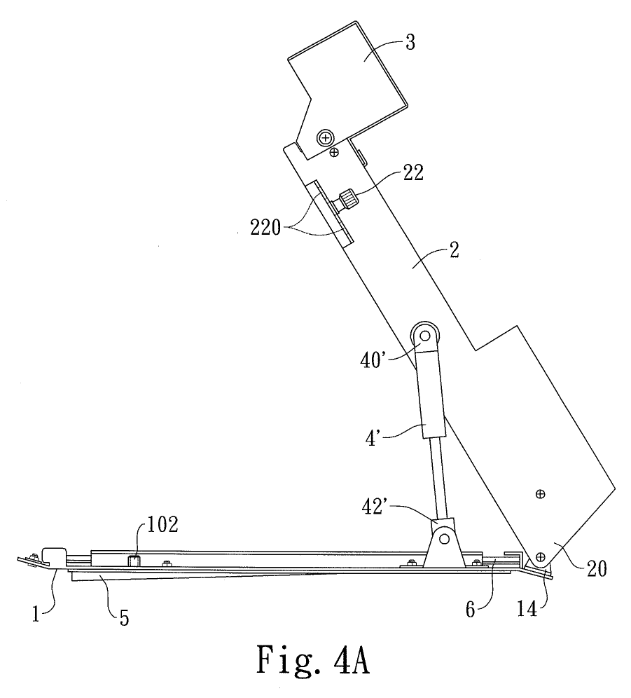

When the case is open, the support element 4 can be pulled up from its original resting location as shown in FIG. 1. As shown in FIG. 4, the free end 40 of the support element 4 can be connected to the rear half casing by screwing the captive screw fastener 22 with threaded seat (i.e. the first connecting part 402), so as to keep the rear half casing 2 apart from the front half casing 1 at a fixed angle. Therefore, after the relative positions of the front and rear half casings are fixed, it is more convenient to replace the broken components inside the case with new ones or clean the interior of the case.

In this embodiment, the captive screw fastener 22 can be used as the second connecting element and as the second connecting part simultaneously. However, it should be noted that, two captive screw fasteners also could be used respectively as a second connecting element and a second connecting part. Besides, two ends of above support element can be exchanged, that is, one end of the support element can be pivotally connected to the rear half casing while another end is designed as a free end used to be screwed to the front half casing.

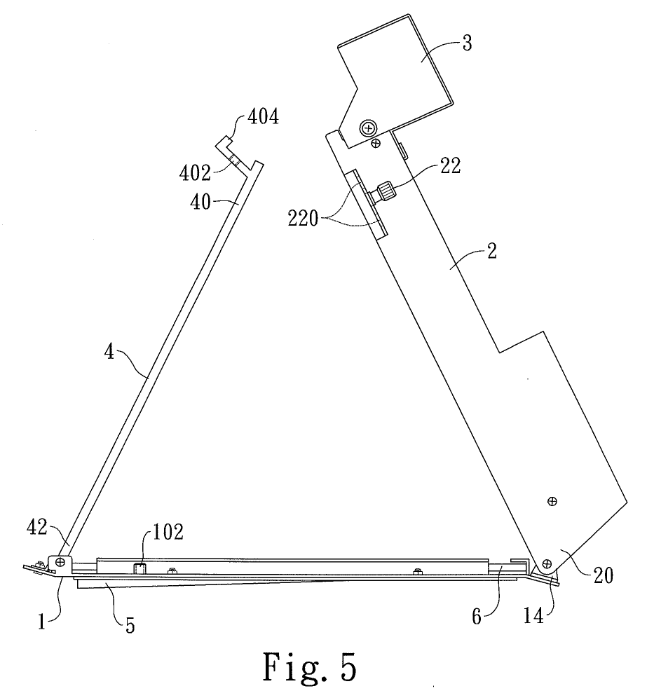

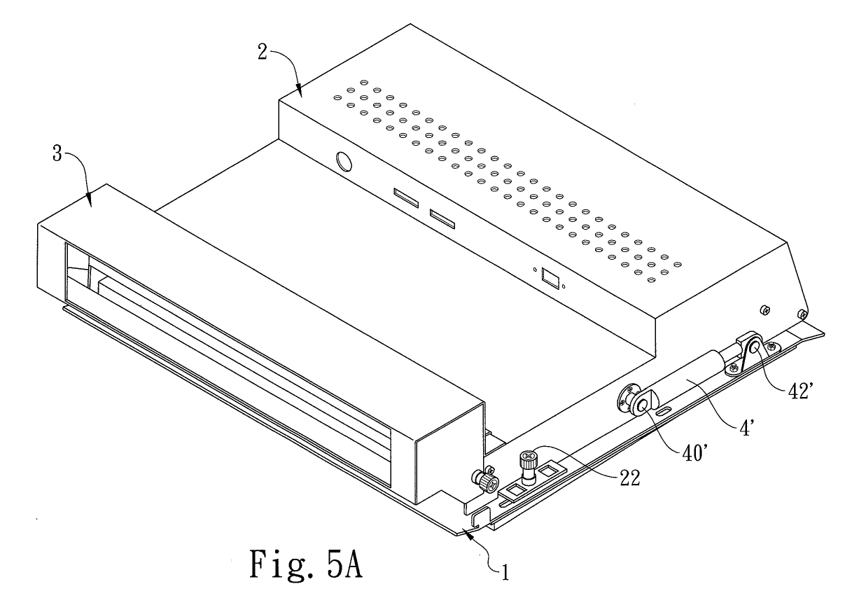

Referring to FIGS. 4A and 5A, a second embodiment of the support element according to the present invention is illustrated. In this embodiment, the support element is a pneumatically actuated support element or a compressible elastic member and has two ends 40′, 42′ respectively pivotally connected to the front half casing 1 and the rear half casing 2. No matter being of a compressible elastic member or a pneumatically actuated support element, the support element is compressible. When the captive screw fastener 22 (i.e. the second connecting element) is unscrewed from the threaded seat 102 (i.e. the first connecting element), as shown in FIG. 4A, the support element 4′ will extend automatically so as to have the rear half casing 2 apart from the front half casing at a fixed angle. When the case is closed by means of screwing the captive screw fastener 22 with the threaded seat 102, ahs shown in FIG. 5A, the support element 4′ is compressed again and located at the lateral side of the case.

Structural improvement for better heat dissipation efficiency:

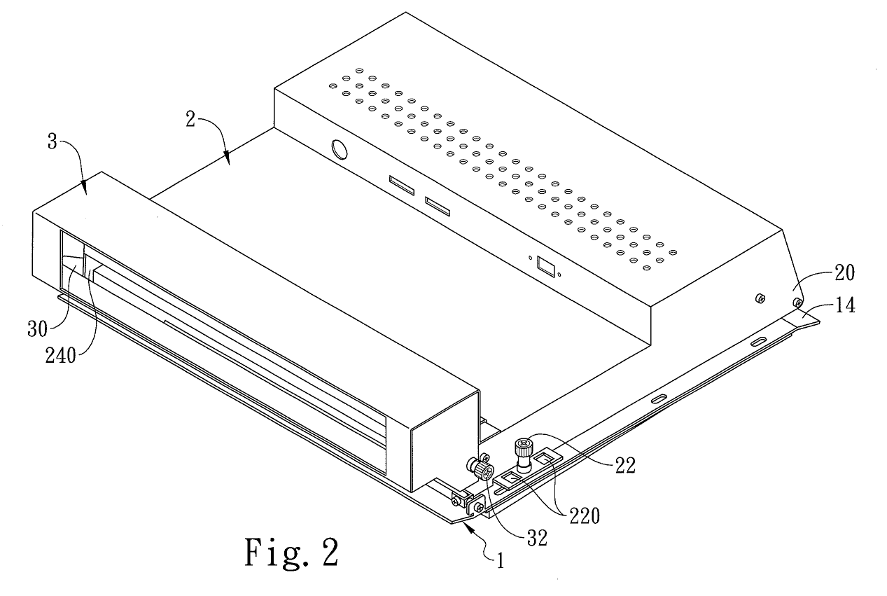

Please refer to FIGS. 1-3, where one embodiment of the case for a display device is illustrated. In this embodiment, a receiving casing 3 is further included in the case for a display device in addition to the front and the rear half casings 1, 2. The receiving casing 3 is detachably connected to a bottom 24 of the rear half casing 2 and is adapted for locating an airflow-generated device 8 therein used for heat dissipation. The airflow-generated device 8 can be one of cross flow fans of various geometrical shapes.

As shown in FIGS. 1 and 3, the receiving casing 3 is provided with a first aperture 30 and the bottom 24 of the rear half casing 2 is provided with a second aperture 240 arranged corresponding to the first aperture 30. Besides, two ends of the receiving casing 3 is respectively provided with a first connector 32 that is screwable with a second connector 26 respectively provided on two lateral sides of the rear half casing 2. In this embodiment, the first connector 32 is a captive screw fastener and the second connector 26 is a seat having threaded hole. In this way, the receiving casing 3 can be easily detached from the rear half casing 2 by unscrewing the first connector 30 from the second connector 26. Moreover, in another embodiment, the first connector also can be a threaded seat while the second connector is a captive screw fastener.

Under this arrangement, as shown in FIG. 3, since the display module 6 is held by the front half casing 1 while the backlight module 7 is held by the rear half casing 2, the airflow generated by the air-flow generated device 8 can to flow into the case via the first and the second apertures 30, 240 and travels through the display module 6 and the backlight module 7. Thereby, the produced heat can be dissipated more efficiently.

Structural improvement for waterproof protection:

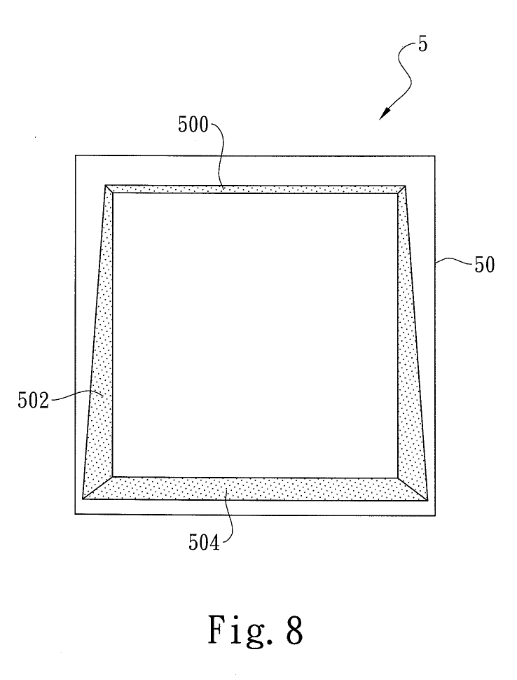

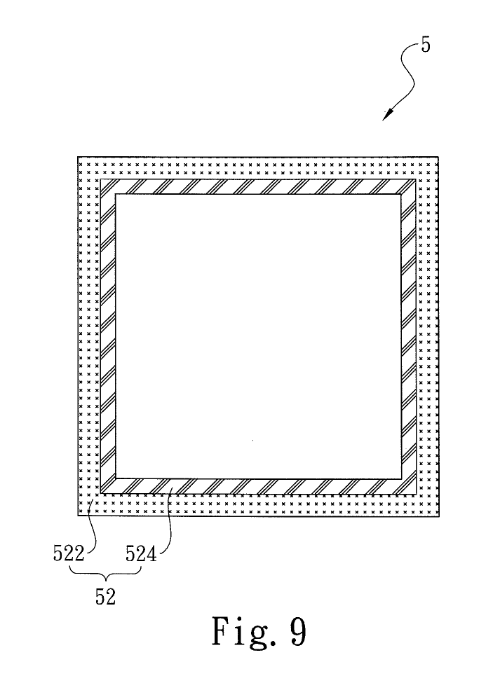

Please refer to FIGS. 8-9, where another embodiment of the case for a display device is illustrated. In this embodiment, the case for a display device further comprises a waterproof frame 5. The waterproof frame 5 has an external surface 50 and an internal surface 52. As shown in FIG. 8, four sides (top, left, right, and bottom sides) of the external surface 50 are respectively provided with a downward-sloping part 500, 502, 504. Besides, each downward-sloping part 502 on lateral sides gradually widens from the topside towards the bottom side. Thereby, liquid, such as water, can be guided by these downward-sloping parts away from the case.

As shown in FIG. 9, the internal surface 52 of the waterproof frame 5 is a flat surface is provided with two layers of waterproof double-sided tapes 522, 524. These two layers of waterproof double-sided tapes 522, 524 are arranged in juxtapositions, via which the waterproof frame 5 can be fastened onto the external surface of the rim portion 10 of the front half casing 1. Preferably, these two layers are made by different kinds of waterproof double-sided tapes.

Accordingly, the present invention has the following advantages:
1. By providing two corresponding sets of connecting element(s) that are screwable with each other and are respectively located at the peripheries of two half casings of the case, it is able to facilitate the replacement or cleaning of the components disposed within the display device according to the present invention.
2. By providing at least a support element between the two half casings, it is able to maintain one half casing apart from another half casing at a fixed angle after the case is open, so as to facilitate the replacement or cleaning of the components disposed within the display device.
3. By providing the case with a receiving casing for locating an airflow-generated device that is detachably connected to the bottom of the rear half casing, the generated airflow can enter the case and travel along between the display module and the backlight module in order to enhance the heat dissipation efficiency.
4. By providing the case with a waterproof frame having downward-sloping parts on the external surface thereof, it is able to obtain better waterproof protection.

Accordingly, as disclosed in the above description and attached drawings, the present invention can provide a case for a display device with structural improvements capable of facilitating the replacement or cleaning of the components disposed within the display device, of improving the heat dissipation efficiency, and of providing better waterproof protection. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. A case for display device, comprising:
a front half casing, including a rim portion and a hollow portion;
a rear half casing, connectable with the front half casing and provided with a second connecting part; and
at least a support element, connected between the front and the rear half casings and used to maintain the rear half casing apart from the front half casing at a fixed angle after the case is open.

2. The case for display device as claimed in claim 1, wherein the support element is a pneumatically actuated support element or a compressible elastic member.

3. The case for display device as claimed in claim 1, wherein one end of the support element is detachably connected to one of the front and rear half casings while another end of the support element is pivotally connected with the other of the front and rear half casings.

4. The case for display device as claimed in claim 3, wherein the end of the support element for detachable connection is provided with a first connecting part that is screwable with a second connecting part arranged at said one of the front and the rear half casing.

5. The case for display device as claimed in claim 4, wherein the first connecting part is a captive screw fastener, and the second connecting part is a seat having a threaded hole.

6. The case for display device as claimed in claim 4, wherein the first connecting part is a seat having a threaded hole, and the second connecting part is a captive screw fastener.

7. The case for display device as claimed in claim 1, further comprising at least one first connecting element and at least one second connecting element, wherein:
the rim portion of the front half casing is adapted for holding a display module so as to locate the display module beneath the hollow portion;
the rear half casing is adapted to receive a light source and a backlight module, in which one side of the rear half casing is pivotally connected with one side of the front half casing;
said at least one first connecting element, provided at the peripheries of the front half casing;
said at least one second connecting element is provided at the peripheries of the front half casing corresponding to the location of the first connecting element, where each second connecting element is screwable with one of the at least one first connecting element.

8. The case for display device as claimed in claim 7, wherein each first connecting element is a captive screw fastener, whereas each second connecting element is a seat having a threaded hole.

9. The case for display device as claimed in claim 7, wherein each first connecting element is a seat having a threaded hole, whereas each second connecting element is a captive screw fastener.

10. The case for display device as claimed in claim 7, further comprising a receiving casing for locating an airflow generated device therein used for heat dissipation, wherein the receiving casing is detachably connected to a bottom of the rear half casing and has a first aperture that is arranged correspondingly to a second aperture arranged on the rear half casing; thereby the airflow generated by the air-flow generated device is able to flow into the case via the first and the second apertures.

11. The case for display device as claimed in claim 10, wherein the receiving casing is provided with at least one first connector and the rear half casing is provided with at least one second connector corresponding to and screwable with the first connector.

12. The case for display device as claimed in claim 11, wherein the first connector is a captive screw fastener, and the second connector is a seat having a threaded hole.

13. The case for display device as claimed in claim 11, wherein the first connector is a seat having a threaded hole, and the second connector is a captive screw fastener.

14. A case for display device, comprising:
a front half casing, including a rim portion and a hollow portion;
a rear half casing, connectable with the front half casing and provided with a second connecting part; and
a receiving casing for locating an airflow generated device therein used for heat dissipation, wherein the receiving casing is detachably connected to a bottom of the rear half casing and has a first aperture that is arranged correspondingly to a second aperture arranged on the rear half casing; thereby the airflow generated by the air-flow generated device is able to flow into the case via the first and the second apertures.

15. The case for display device as claimed in claim 14, wherein the receiving casing is provided with at least one first connector and the rear half casing is provided with at least one second connector corresponding to and screwable with the first connector.

16. The case for display device as claimed in claim 14, further comprising at least one first connecting element and at least one second connecting element, wherein:
the rim portion of the front half casing is adapted for holding a display module so as to locate the display module beneath the hollow portion;
the rear half casing is adapted to receive a light source and a backlight module, in which one side of the rear half casing is pivotally connected with one side of the front half casing;
said at least one first connecting element, provided at the peripheries of the front half casing;
said at least one second connecting element is provided at the peripheries of the front half casing corresponding to the location of the first connecting element, where each second connecting element is screwable with one of the at least one first connecting element.

17. The case for display device as claimed in claim 16, further comprising at least a support element, connected between the front and the rear half casings and used to maintain the rear half casing apart from the front half casing at a fixed angle after the case is open.

18. The case for display device as claimed in claim 17, wherein the support element is a pneumatically actuated support element or a compressible elastic member.

19. The case for display device as claimed in claim 17, wherein one end of the support element is detachably connected to one of the front and rear half casings while another end of the support element is pivotally connected with the other of the front and rear half casings.

20. The case for display device as claimed in claim 19, wherein the end of the support element for detachable connection is provided with a first connecting part that is screwable with a second connecting part arranged at said one of the front and the rear half casing.
